(19) United States
(12) Patent Application Publication
(10) Pub. No.: US 2003/0072878 A1
(43) Pub. Date: Apr. 17, 2003

(54) Method of protecting metal parts of turbomachines having holes and cavities by aluminizing the parts

(75) Inventors: Jean-Paul Fournes, Dannemois (FR); Guillaume Oberlaender, Paris (FR); Catherine Richin, Roinville Sous Dourdan (FR)

Correspondence Address: OBLON, SPIVAK, MCCLELLAND, MAIER & NEUSTADT, P.C., 1940 DUKE STREET, ALEXANDRIA, VA, 22314, US

(73) Assignee: SNECMA MOTEURS, PARIS (FR)

(21) Appl. No.: 10/268,701

(22) Filed: Oct. 11, 2002

(30) Foreign Application Priority Data
Oct. 16, 2001 (FR) 01 13315

(51) Int. Cl. C23C 16/00

(52) U.S. Cl. 427/250

(57) ABSTRACT

At least one gaseous precursor of the deposit to be made comprising an aluminum compound is brought by means of a carrier gas into contact with the surfaces of the part which is placed inside an enclosure. The carrier gas is selected from helium and argon and the pressure inside the enclosure is selected in such a manner that the mean free path of the carrier gas molecules is at least twice as long as that of argon molecules under atmospheric pressure. The method is suitable in particular for aluminizing gas turbine blades that have internal holes and cavities.

### BACKGROUND OF THE INVENTION

The invention relates to protecting metal parts presenting holes and cavities against oxidation at high temperature.

The field of application of the invention is that of protecting turbomachine parts such as turbine parts, in particular blades, that present internal cavities for passing a flow of cooling air, said air being delivered via feed holes or passages that generally pass through the roots of the blades, and generally being exhausted via vent holes that open out to the outside surfaces of the blades.

In spite of being made out of metal superalloys, generally based on nickel or cobalt, it is necessary to provide such parts with a coating to protect them against oxidation, and capable of protecting them against oxidation at the ever increasing temperatures at which it is desired to operate turbomachines in order to improve their efficiency.

One method of protection that is in widespread use is aluminization by vapor deposition. That method is well known, and reference can be made in particular to document FR 1 433 497. It consists in placing one or more parts to be protected in an enclosure having a gaseous mixture flowing therethrough, the mixture comprising an aluminum compound such as a halide together with a dilution gas or carrier gas. The halide is produced by reaction between a halogen, e.g. chlorine or fluorine, and a meal donor containing aluminum, e.g. a metal alloy of aluminum with one or more of the metal components of the material from which the parts to be protected are made. The dilution gas dilutes and entrains the gaseous mixture so as to bring the halide into contact with the parts in order to form the desired deposit on the surfaces thereon. The commonly used dilution gas is argon. Hydrogen is also mentioned in above-cited document FR 1 433 497, but it is very difficult to use in practice because of the danger it presents.

The conventional method of aluminization by vapor deposition does indeed enable a satisfactory protective coating to be formed on the outside surfaces of the parts, but no coating is formed on the inside walls of the holes and cavities. Unfortunately, in spite of the flow of cooling air, the temperature of these inside walls can reach values such that internal oxidation phenomena can arise, at least locally. The Applicant has observed that this oxidation can give rise to flaking of the material from which the parts are made and that flakes torn from the internal walls by the flow of air can then partially obstruct the vent holes. This gives rise to irregularity in the protective film formed on the outside wall by the air escaping through the vent holes, and to the appearance of hot points that lead to parts being damaged locally.

In addition, the aluminization deposit tends to accumulate around the outside orifices of the holes. This leads to the presence of constrictions which can have a considerable effect on the flow of cooling air by giving rise to head losses and by encouraging zones of stagnant air to appear. It is possible to envisage reboring the holes, but that is difficult to perform since it needs to be done very accurately and it must avoid damaging the protective coating in the vicinity of the orifices, and in any event it constitutes an additional operation that is expensive.

The Applicant has also observed that large extra thicknesses of deposit, in particular around the air inlet orifices at the roots of the blades, present a non-negligible risk not only of causing the coating to crack, but also of cracking the underlying metal material constituting the blades.

Unlike the blade material, the coating is subject to cracking caused by the thermal cycling to which the blades are subjected. When the coating is thick, a crack appearing across the coating tends to propagate into the underlying material (which does not happen when the coating is thin).

Unfortunately, cracking in the blade material in the vicinity of their roots can lead to the blades themselves being destroyed, and can therefore have consequences that are potentially very severe.

### OBJECT AND BRIEF SUMMARY OF THE INVENTION

An object of the invention is to provide a method enabling protection to be obtained by aluminization both on the outside walls and on the inside walls of a metal turbomachine part that has holes and/or cavities communicating with the outside, the method serving to avoid the problems mentioned above.

This object is achieved by a method in which at least one gaseous precursor of the deposit to be made, said precursor comprising an aluminum compound, is brought by means of a carrier gas into contact with the surfaces of a part placed in an enclosure, in which method, according to the invention, the carrier gas is selected from helium and aluminum and the pressure inside the enclosure is selected in such a manner that the mean free path of the carrier gas molecules is at least twice as long as that of argon molecules under atmospheric pressure.

Lengthening the mean free path of the carrier gas molecules makes penetration into the holes and/or the cavities of the part easier and thus enables molecules of the precursor gas to be taken more deeply into contact with the inside surfaces of the part. This makes it possible both to form a protective coating on the inside surfaces and to limit the formation of extra thicknesses of deposit around the orifices of the holes and/or cavities.

In an implementation of the invention, helium is used as the carrier gas and the method may be implemented under atmospheric pressure, or under a pressure that is less than atmospheric pressure.

In another implementation of the invention, argon is used as the carrier gas and the method is advantageously carried out under pressure not greater than 50 kilopascals (kPa), and preferably not greater than 25 kPa.

Advantageously, the part is made with holes which, at least in their portions adjacent to their outside orifices, present a diameter that increases going towards the outside. The flared shape of the holes serves to compensate for the thickness of the coating tapering away from the outside orifice so that after aluminization, a hole is obtained of diameter that is substantially constant, as desired.

### BRIEF DESCRIPTION OF THE DRAWINGS

The invention will be better understood on reading the following description given by way of non-limiting indication and with reference to the accompanying drawings, in which:

FIG. 1 is a diagrammatic elevation view of a turbine blade having an internal cooling circuit;

FIG. 2 is a diagrammatic cross-section on plane II-II of FIG. 1;

FIG. 3 is a very diagrammatic view of an installation enabling a method in accordance with the invention to be implemented; and

FIGS. 4 to 6 are highly diagrammatic, showing a coating formed by aluminization in the vicinity of the orifice of a vent hole in a blade such as the blade shown in FIGS. 1 and 2, respectively as obtained using a prior art method, using a first method of the invention, and using a variant method of the invention.

### DETAILED DESCRIPTION OF IMPLEMENTATIONS

Implementations of the invention are described below for application to a method of forming a protective coating for a gas turbine blade that has internal holes and cavities through which cooling air can flow. It is immediately apparent that the method is suitable for use with any metal turbomachine part that presents holes and/or cavities communicating with the outside.

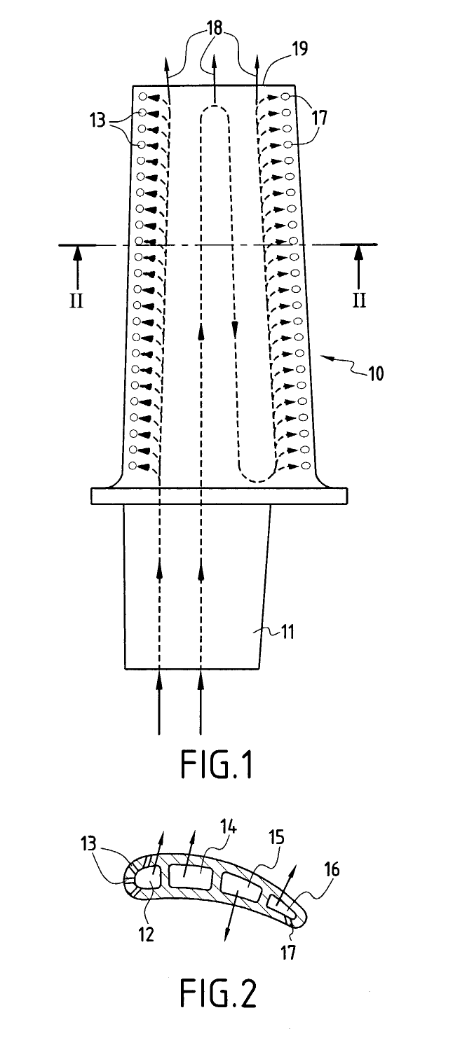

A gas turbine blade 10 is shown diagrammatically in FIGS. 1 and 2.

In conventional manner, the blade 10 is made of a nickel or cobalt based superalloy and it contains internal cavities 12, 14, 15, and 16 extending over the full height of the blade and enabling cooling air to flow therethrough.

The cavity 12 situated beside the leading edge is fed from a passage formed through the blade root 11. The air penetrating into the cavity 12 escapes via holes 13 through the leading edge of the blade so as to form a protective film of air on the outside of the leading edge.

Air admitted into the cavity 14 through a passage formed in the blade root travels in series along the cavities 14, 15, and 16. This air escapes through vent holes 17 opening out into the concave or “lower” surface of the blade in the vicinity of its trailing edge and also opening out into the cavity 16. Additional vent holes could also be formed through the lower surface, opening out into the cavity 15 or even into the cavity 14.

Holes referenced 18 in FIG. 1 put the tip 19 of the blade into communication with the internal cavities. The holes 18 correspond to locations for the supports of the cores used to occupy the internal cavities while the blade is being cast.

The path followed by the cooling air is shown by dashed lines and arrows in FIGS. 1 and 2.

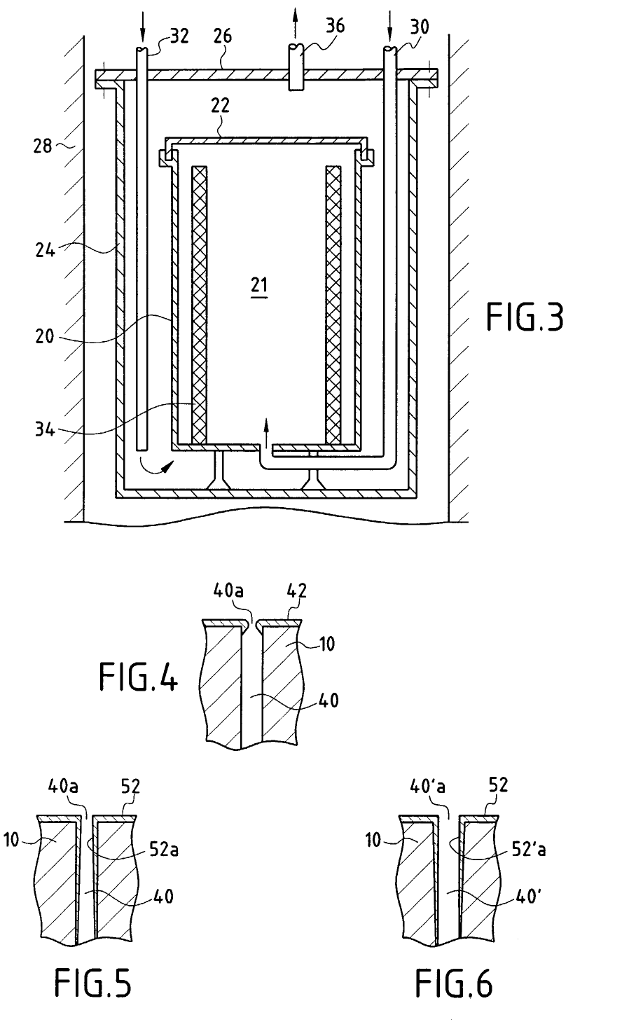

A coating providing protection against oxidation at high temperature is formed on the outside surface and on the inside surfaces of the blade 10 by a method of the invention, e.g. using a vapor aluminization installation as shown in FIG. 3.

This installation comprises a vessel 20 closed by a cover 22 in non-leaktight manner and supported inside a pot 24. The pot is closed in leaktight manner by a cover 26 and is located inside an oven 28.

A pipe 30 feeds the enclosure 21 defined by the vessel 20 with a carrier gas (or dilution gas). The same gas is injected into the pot 24 outside the vessel 20 via a pipe 32. This sweeping gas is recovered via a pipe 36 passing through the cover 26.

Inside the vessel 20 there is disposed a donor 34 in granular or powder form, for example. The donor is generally constituted by an alloy of aluminum together with one or more of the metals constituting the blades to be aluminized. An activator enabling a halide to be formed with the donor is also introduced into the enclosure in the form of a powder. Commonly used activators are ammonium fluoride NH₄F and aluminum fluoride AlF₃.

The blades to be aluminized are placed inside the enclosure 21 being supported by or suspended from tooling (not shown) in conventional manner.

The temperature of the oven is adjusted so that inside the oven the temperature generally lies in the range 950° C. to 1200° C. suitable for forming a gaseous halide by reaction between the donor and the activator. Aluminum is deposited by the halide decomposing on coming into contact with the surfaces of the blades. The function of the carrier gas is to facilitate transport of the halide molecules.

In a first implementation of the invention, the carrier gas used is helium.

In comparison with argon, the gas that is usually used, helium molecules have a mean free path of considerably greater length, for any given pressure. The mean free path length L is usually defined as being proportional to 1/P.D² where P is pressure and D is the diameter of the molecule. The ratio L_{He}/L_{Ar} between the mean free paths of helium molecules and argon molecules is approximately equal to 3, at atmospheric pressure.

By lengthening the mean free path of the carrier gas molecules, diffusion of the halide within the holes and cavities of the blade is facilitated, such that aluminization can be performed on the inside surfaces of the blade, at least over a certain distance from the outside orifices of the holes and cavities. This provides internal protection against oxidation at high temperature.

This is illustrated very diagrammatically in FIGS. 4 and 5.

FIG. 4 shows the result of conventional argon aluminization in the vicinity of the orifice of a blade vent hole 40. It can be seen that the deposit 42 formed by aluminization is restricted to the outside surface and does not extend along the inside wall of the hole 40, and thus extends even less over the walls of the internal cavity in the blade. Furthermore, the deposit 42 obstructs the outside orifice 40a of the hole 40 to some extent, thereby disturbing air flow.

FIG. 5 shows the result of using a carrier gas having molecules with a longer mean free path, it can be seen that the deposit 52 formed by aluminization extends not only over the outside surface of the blade, but also over the inside surface of the vent hole 40, and from there can even extend over the surface of the cavity inside the blade.

As shown in exaggerated manner in FIG. 5, the thickness of the internal deposit 52a decreases going away from the outside orifice 40a of the hole 40. Its outlet section is thus reduced, even though the constriction shown in FIG. 4 is not presented.

In a variant, in order to avoid this reduction in hole section after aluminization, the blade can be made using vent holes of section that increases progressively going towards the outside, like the hole 40′ in FIG. 6. The way in which the section varies is determined in such a manner as to compensate for the decreasing thickness of the internal deposit 52′a as observed going away from the outside orifice 40′a, such that after aluminization, vent holes are obtained that are of substantially constant diameter and of the desired size. No machining is then required of the holes for finishing purposes.

In a second implementation of the invention, the carrier gas used is argon, and the aluminization process is performed under low pressure, thereby likewise lengthening the mean free path of the molecules of the carrier gas.

Thus, after the blades have been loaded into the enclosure 21 of the FIG. 3 installation, and after the pot 24 has been closed in leaktight manner, the atmosphere inside the pot 24 and the vessel 20 is purged under argon and its pressure is reduced by pumping via the pipe 28 so as to bring the pressure inside the pot 24 and the vessel 20 down to a relatively low value, for example a value of less than 5 kPa.

Thereafter, a continuous flow of argon is admitted via the pipe 30 so as to maintain the pressure inside the pot and the vessel 20 at a value that is lower than atmospheric pressure. A value should be selected that is no greater than 50 kPa, and preferably no greater than 25 kPa, with the ratio L_{Ar} low/L_{Ar atm} between the mean free path lengths of argon molecules at low pressure and at atmospheric pressure then being equal to at least 2, and preferably equal to at least 4.

### Tests

A turbine blade similar to that shown in FIGS. 1 and 2 was aluminized using an installation of the type shown in FIG. 3, the donor being a chromium-aluminum alloy having 30% to 35% aluminum, and the activator was AlF₃.

The process was carried out at a temperature inside the enclosure equal to about 1150° C. for a duration of about 3 h.

Three tests A, B, and C were performed, respectively with argon under atmospheric pressure (prior art method of aluminization by vapor deposition), with helium, and with argon under low pressure equal approximately to 13 kPa.

The table below gives the thicknesses of the coating (in micrometers, μm) measured on the outside surface of the blade and on the inside surfaces of cavities, respectively in the vicinity of the root, in the middle, and in the vicinity of the tip.

| | | A | B | C |
|---|---|---|---|---|
| Top | outside | 90 | 90 | 90 |
| | inside | 0 | 25 | 50 |
| Middle | outside | 90 | 85 | 95 |
| | inside | 0 | 0 | 70 |
| Root | outside | 90 | 90 | 90 |
| | inside | 0 | 40 | 65 |

Whereas a substantially uniform outside coating is obtained in all three cases, only the methods performed in accordance with the invention were able to coat the inside surfaces.

The method using argon at low pressure enables the inside surfaces of the holes and cavities to be aluminized completely, with a detailed examination thereof showing that the insides were coated fully with a minimum thickness of 30 μm.

In contrast, the method using helium was not able to achieve coating internally all the way to the core of the blade.

It should be observed that in test C (Ar at low pressure), the ratio L_{Ar low}/L_{Ar atm} was equal to about 7.8, whereas in test B (He at atmospheric pressure), the ratio L_{He}/L_{Ar atm} was equal to about 3.

The process of aluminization using a carrier gas constituted by helium could also be performed at low pressure in order to achieve a ratio L_{Ar low}/L_{Ar atm} greater than 3, thereby leading to complete aluminization of the inside surfaces of the blade.

What is claimed is:

1/ A method of aluminization by vapor deposition for protecting a metal turbomachine part against high temperature oxidation, the part having holes and/or cavities communicating with the outside, in which method at least one gaseous precursor of the deposit to be made, said precursor comprising an aluminum compound, is brought into contact with the surfaces of the part placed in an enclosure by means of a carrier gas, wherein the carrier gas is selected from helium and aluminum and the pressure inside the enclosure is selected in such a manner that the mean free path of the carrier gas molecules is at least twice as long as that of argon molecules under atmospheric pressure.

2/ A method according to claim 1, the method being performed under atmospheric pressure using helium as the carrier gas.

3/ A method according to claim 1, the method being performed under a pressure lower than atmospheric pressure, using helium as the carrier gas.

4/ A method according to claim 1, the method being performed under a pressure no greater than 50 kPa using argon as the carrier gas.

5/ A method according to claim 1, the method being performed under a pressure no greater than 25 kPa using argon as the carrier gas.

6/ A method according to claim 1, wherein the part is made with holes which, at least in the vicinity of their outside orifices, present a diameter that increases going towards the outside.
